(19) United States
(12) Patent Application Publication
(10) Pub. No.: US 2026/0040637 A1
(43) Pub. Date: Feb. 5, 2026

(54) NANOSHEET 1T-4R MASK-PROGRAMMED MULTI-LEVEL READ-ONLY MEMORY

(71) Applicant: International Business Machines Corporation, Armonk, NY (US)

(72) Inventors: Tsung-Sheng Kang, Ballston Lake, NY (US); Bahman Hekmatshoartabari, White Plains, NY (US); Alexander Reznicek, Troy, NY (US); Jingyun Zhang, Albany, NY (US)

(21) Appl. No.: 18/794,278

(22) Filed: Aug. 5, 2024

(51) Int. Cl. H01L 29/06; H01L 23/528; H01L 29/423; H01L 29/66; H01L 29/775; H01L 29/786; H10B 20/20; H10B 99/00

(52) U.S. Cl. CPC H10D 62/121; H01L 23/5283; H01L 23/5286; H10B 20/20; H10B 99/14; H10D 30/014; H10D 30/43; H10D 30/6735; H10D 30/6757; H10D 64/017

(57) ABSTRACT

A nanosheet 1T-4R mask programed multi-level read-only memory component includes a plurality of nanosheet channels between a first source/drain and a second source/drain and a gate around the plurality of nanosheet channels. The component includes a first resistor upon a frontside surface of the first source/drain, a second resistor upon a frontside surface of the second source/drain, a third resistor upon a backside surface of the first source/drain, and a fourth resistor upon a backside surface of the second source/drain. Respective frontside contacts electrically connect the first resistor, the second resistor, and the gate to a frontside backend of line (BEOL) network. Respective backside contacts electrically connect the third resistor and the fourth resistor to a backside power delivery network (BSPDN).

### BACKGROUND

The present disclosure relates to the electrical, electronic, and computer fields. In particular, the present disclosure relates to nanosheet 1T-4R mask programed multi-level read-only memory.

Mask-programmed, read-only memory (ROM), also known as mask ROM or factory-programmed ROM is a form of a read-only memory whose contents are programmed by the integrated circuit manufacturer (rather than by the user). The desired memory contents are furnished by the customer to the device manufacturer. The desired data is converted into a custom mask layer for the final metallization of interconnections on the memory chip (hence the name). Mask ROM is beneficial in high-volume production of well-established and widely-used subsystems, such as the bootstrapping firmware for the processor, various firmware for internal control of self-contained devices, as well as simple and mature subsystems (such as keyboard and communication controllers) in modern PCs. As the CMOS technology evolves with scaling and new device structures and integration schemes become available, there is a need for innovative structures and fabrication methods for mask programmed ROM to take advantage of the scaling benefits made available by these emerging CMOS technologies.

### SUMMARY

Embodiments of the present disclosure include structures and fabrication methods for a 1T-4R mask ROM, which enables multiple levels of memory for high-density storage with minimal levels of mask programming.

Embodiments of the present disclosure include a nanosheet 1T-4R mask programed multi-level read-only memory component. The component includes a first source/drain; a second source/drain; a plurality of nanosheet channels between the first source/drain and the second source/drain. The component further includes a first resistor upon a frontside surface of the first source/drain. The component further includes a second resistor upon a frontside surface of the second source/drain. The component further includes a replacement metal gate above the plurality of nanosheet channels and around, but electrically isolated from, the first resistor and the second resistor. The component further includes a third resistor upon a backside surface of the first source/drain. The component further includes a fourth resistor upon a backside surface of the second source/drain. The component further includes a first contact electrically connecting the first resistor to a frontside backend of line network. The component further includes a second contact electrically connecting the third resistor to the frontside backend of line network. The component further includes a gate contact electrically connecting the replacement metal gate to the frontside backend of line network. The component further includes a third contact electrically connecting the third resistor to a backside power delivery network. The component further includes a fourth contact electrically connecting the fourth resistor to the backside power delivery network.

Additional embodiments of the present disclosure include a method for forming a nanosheet 1T-4R mask programed multi-level read-only memory component. The method includes providing a plurality of nanosheet channels above a bottom dielectric isolation and beneath a plurality of PC spacers. The method further includes forming a first gate module recess and a second gate module recess in the plurality of nanosheet channels. The method further includes forming a first source/drain recess in the plurality of nanosheet channels beneath the first gate module recess and a second source/drain recess in the plurality of nanosheet channels beneath the second gate module recess. The method further includes depositing a first placeholder into a silicon layer at a bottom of the first source/drain recess and a second placeholder into the silicon layer at a bottom of the second source/drain recess. The method further includes depositing a first source/drain in the first source/drain recess above the first placeholder and a second source/drain in the second source/drain recess above the second placeholder. The method further includes depositing a first resistor electrically coupled to a frontside surface of the first source/drain and adjacent at least one of the PC spacers and a second resistor electrically coupled to a frontside surface of the second source/drain adjacent at least one of the PC spacers. The method further includes depositing a replacement metal gate between the first resistor and the second resistor, above the plurality of nanosheet channels and adjacent to at least two of the PC spacers. The method further includes depositing a first contact electrically coupled to the first resistor, a second contact electrically coupled to the second resistor, and a gate contact electrically coupled to the replacement metal gate. The method further includes depositing a backend of line network electrically coupled to the first contact, the second contact, and the gate contact. The method further includes removing the silicon layer from around the first placeholder and the second placeholder to expose the first placeholder, the second placeholder, and the bottom dielectric isolation. The method further includes depositing a layer around the first placeholder and the second placeholder. The method further includes removing the first placeholder and the second placeholder. The method further includes depositing a third resistor electrically coupled to a backside surface of the first source/drain and a fourth resistor electrically coupled to a backside surface of the second source drain. The method further includes depositing a third contact electrically coupled to the third resistor and a fourth contact electrically coupled to the fourth resistor. The method further includes depositing a backside power delivery network electrically connecting the third contact and electrically connecting the fourth contact.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

FIG. 1 illustrates an equivalent circuit of the disclosed 1T4R bit cell component, in accordance with embodiments of the present disclosure.

FIG. 2A-1 and FIG. 2A-2 illustrate a flow diagram of an exemplary method that can be implemented in accordance with embodiments of the present disclosure.

FIG. 2B illustrates a flow diagram of optional exemplary method steps that can be implemented in accordance with embodiments of the present disclosure.

FIG. 3 illustrates a cross-sectional view of an example of a component following the performance of a portion of the example method of FIG. 2A-1 and FIG. 2A-2, in accordance with embodiments of the present disclosure.

FIG. 4 illustrates a cross-sectional view of an example of a component following the performance of a portion of the example method of FIG. 2A-1 and FIG. 2A-2, in accordance with embodiments of the present disclosure.

FIG. 5A illustrates a cross-sectional view of an example of a component following the performance of a portion of the example method of FIG. 2A-1 and FIG. 2A-2, in accordance with embodiments of the present disclosure.

FIG. 5B illustrates a cross-sectional view of an example of a component following the performance of a portion of the example method of FIG. 2A-1 and FIG. 2A-2, in accordance with embodiments of the present disclosure.

FIG. 5C illustrates a cross-sectional view of an example of a component following the performance of a portion of the example method of FIG. 2A-1 and FIG. 2A-2, in accordance with embodiments of the present disclosure.

FIG. 5D illustrates a cross-sectional view of an example of a component following the performance of a portion of the example method of FIG. 2A-1 and FIG. 2A-2, in accordance with embodiments of the present disclosure.

FIG. 5E illustrates a cross-sectional view of an example of a component following the performance of a portion of the example method of FIG. 2 A-1 and FIG. 2A-2, in accordance with embodiments of the present disclosure.

FIG. 6 illustrates a cross-sectional view of an example of a component following the performance of a portion of the example method of FIG. 2A-1 and FIG. 2A-2, in accordance with embodiments of the present disclosure.

FIG. 7 illustrates a cross-sectional view of an example of a component following the performance of a portion of the example method of FIG. 2A-1 and FIG. 2A-2, in accordance with embodiments of the present disclosure.

FIG. 8 illustrates a cross-sectional view of an example of a component following the performance of a portion of the example method of FIG. 2A-1 and FIG. 2A-2, in accordance with embodiments of the present disclosure.

FIG. 9 illustrates a cross-sectional view of an example of a component following the performance of a portion of the example method of FIG. 2A-1 and FIG. 2A-2, in accordance with embodiments of the present disclosure.

FIG. 10 illustrates a cross-sectional view of an example of a component following the performance of a portion of the example method of FIG. 2A-1 and FIG. 2A-2, in accordance with embodiments of the present disclosure.

FIG. 11 illustrates a cross-sectional view of an example of a component following the performance of a portion of the example method of FIG. 2A-1 and FIG. 2A-2, in accordance with embodiments of the present disclosure.

FIG. 12 illustrates a cross-sectional view of an example of a component following the performance of a portion of the example method of FIG. 2A-1 and FIG. 2A-2, in accordance with embodiments of the present disclosure.

FIG. 13 illustrates a cross-sectional view of an example of a component following the performance of a portion of the example method of FIG. 2A-1 and FIG. 2A-2, in accordance with embodiments of the present disclosure.

FIG. 14 illustrates a cross-sectional view of an example of a component following the performance of a portion of the example method of FIG. 2B, in accordance with embodiments of the present disclosure.

FIG. 15 illustrates a cross-sectional view of an example of a component following the performance of a portion of the example method of FIG. 2B, in accordance with embodiments of the present disclosure.

FIG. 16 illustrates a cross-sectional view of an example of a component following the performance of a portion of the example method of FIG. 2B, in accordance with embodiments of the present disclosure.

### DETAILED DESCRIPTION

Aspects of the present disclosure relate generally to the electrical, electronic, and computer fields. In particular, the present disclosure relates to semiconductor devices, especially read only memory. While the present disclosure is not necessarily limited to such applications, various aspects of the disclosure may be appreciated through a discussion of various examples using this context.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

The below-referenced U.S. Patent(s) and/or U.S. Patent Application(s) disclose embodiments that are useful for the purposes for which they are intended. The entire contents of U.S. Pat. No(s). 10,011,920 are hereby expressly incorporated by reference herein for all purposes.

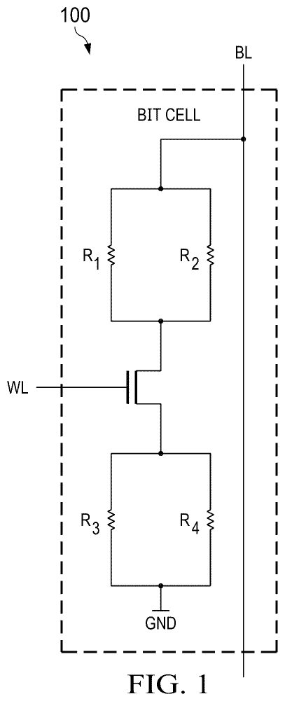

Referring to FIG. 1, a schematic circuit representation 100 for an embodiment of the disclosed 1T-4R bit cell is shown. Of course, embodiments of the instant disclosure are not limited to just the corresponding 1T-4R mask-programmed read-only memory (ROM), or just this schematic circuit representation 100 for this embodiment of the 1T-4r bit cell.

R₁-R₄ may be, e.g. Si-based resistors with different doping concentrations and therefore resistance values. The total cell resistance is given by R_{cell}=(R₁|R₂)+ (R₃|R₄)=R₁R₂/(R₁+R₂)+R₃R₄/(R₃+R₄).

With only 2 different doping levels (i.e. 2 possible resistance values), 4 resistance levels per cell can be achieved. For example, if 2 sets of high-resistance (R_{H}) and low-resistance (R_{L}) Si-based resistors are formed using lightly-doped and highly-doped Si, respectively; the 4 possible resistance levels are:

$${R}_{H} ‖ {R}_{H} + {R}_{H} ‖ {R}_{H} = {R}_{H}$$

$${R}_{L} ‖ {R}_{L} + {R}_{L} ‖ {R}_{L} = {R}_{L}$$

$${R}_{H} ‖ {R}_{L} + {R}_{H} ‖ {R}_{L} = 2 {R}_{H} {R}_{L} / ( {R}_{H} + {R}_{L} )$$

$${R}_{H} ‖ {R}_{H} + {R}_{L} ‖ {R}_{L} = ( {R}_{H} + {R}_{L} ) / 2$$

For example, if R_{H}=10 KΩ and R_{L}=1 KΩ, the 4 resistance levels are 1, 1.8, 5.5 and 10 (all KΩ), which can be easily resolved during readout. Clearly, more resistance levels can be achieved with more masking steps, if desired.

The processes, steps, and structures described below do not form a complete process flow for manufacturing integrated circuits. The disclosure can be practiced in conjunction with integrated circuit fabrication techniques currently used in the art, and only so much of the commonly practiced process steps are included as necessary for an understanding of the different examples of the present disclosure. Many of the figures represent cross sections of a portion of an integrated circuit during fabrication and are not drawn to scale, but instead are drawn so as to illustrate different illustrative features of the disclosure.

In general, the various processes for a semiconductor chip or micro-chip that will be packaged into an IC fall into three general categories, namely, deposition, removal/etching, and patterning/lithography.

Deposition is any process that grows, coats, or otherwise transfers a material onto the substrate. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the substrate surface that would otherwise require higher temperatures associated with conventional CVD. Energetic ion bombardment during PECVD deposition can also improve the film's electrical and mechanical properties.

Removal/etching is any process that removes material from the substrate. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on substrates. With RIE the plasma is generated under low pressure (vacuum) by an electromagnetic field. High-energy ions from the RIE plasma attack the substrate surface and react with it to remove material.

Patterning/lithography is the formation of three-dimensional relief images or patterns on the semiconductor substrate for subsequent transfer of the pattern to a layer arranged beneath the pattern. In semiconductor lithography, the patterns are formed by a light sensitive polymer called a photoresist.

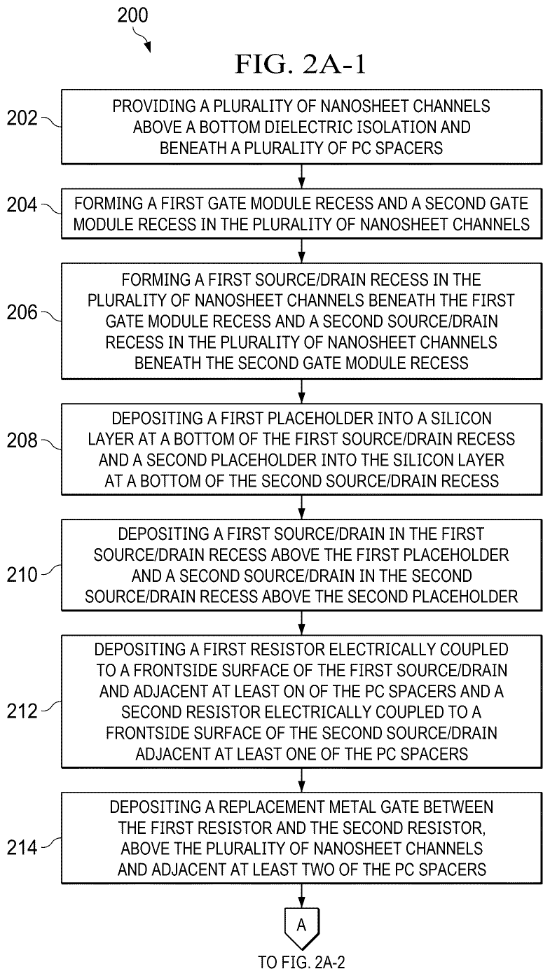

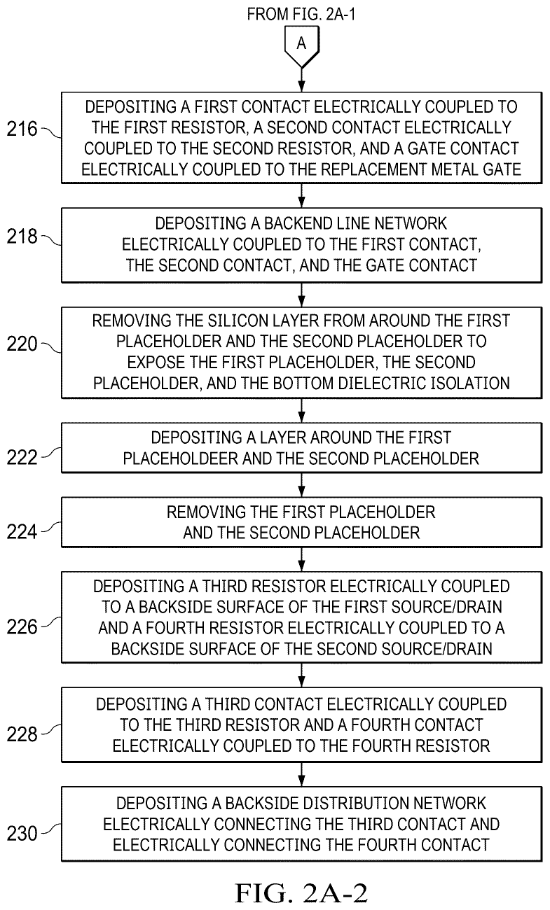

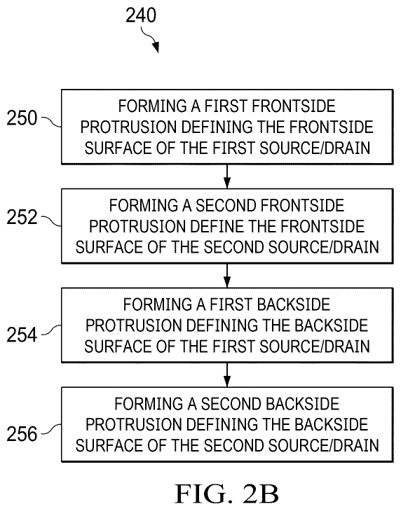

FIG. 2A-1 and FIG. 2A-2 shows a first flowchart 200 illustrating steps for forming an embodiment of 1T-4R mask-programmed read-only memory (ROM). FIG. 2B shows a second flowchart 240 illustrating optional steps for forming an embodiment of the 1T-4R mask-programmed read-only memory (ROM).

Step 202 includes providing a plurality of nanosheet channels above a bottom dielectric isolation and beneath a plurality of PC spacers. Step 204 includes forming a first gate module recess and a second gate module recess in the plurality of nanosheet channels. Step 206 includes forming a first source/drain recess in the plurality of nanosheet channels beneath the first gate module recess and a second source/drain recess in the plurality of nanosheet channels beneath the second gate module recess.

Step 208 includes depositing a first placeholder into a silicon layer at the bottom of the first source/drain recess and a second placeholder into the silicon layer at a bottom of the second source/drain recess. Step 210 includes depositing a first source/drain in the first source/drain recess above the first placeholder and a second source/drain in the second source/drain recess above the second placeholder. Step 212 includes depositing a first resistor electrically coupled to a frontside surface of the first source/drain and adjacent at least one of the PC spacers and a second resistor electrically coupled to a frontside surface of the second source/drain adjacent at least one of the PC spacers. Step 214 includes depositing a replacement metal gate between the first resistor and the second resistor, above the plurality of nanosheet channels and adjacent at least two of the PC spacers. Step 216 includes depositing a first contact electrically coupled to the first resistor, a second contact electrically coupled to the second resistor, and a gate contact electrically coupled to the replacement metal gate. Step 218 includes depositing a backend of line network electrically coupled to the first contact, the second contact, and the gate contact.

Step 220 includes removing the silicon layer from around the first placeholder and the second placeholder to expose the first placeholder, the second placeholder, and the bottom dielectric isolation. Step 222 includes depositing a layer around the first placeholder and the second placeholder. Step 224 includes removing the first placeholder and the second placeholder.

Step 226 includes depositing a third resistor electrically coupled to a backside surface of the first source/drain and a fourth resistor electrically coupled to a backside surface of the second source drain. Step 228 includes depositing a third contact electrically coupled to the third resistor and a fourth contact electrically coupled to the fourth resistor. Step 230 includes depositing a backside power delivery network electrically connecting the third contact and electrically connecting the fourth contact.

Referring to FIG. 2B, optional step 250 includes forming a first frontside protrusion defining the frontside surface of the first source/drain. Optional step 252 includes forming a second frontside protrusion to define the frontside surface of the second source/drain. Optional step 254 includes forming a first backside protrusion defining the backside surface of the first source/drain. Optional step 256 includes forming a second backside protrusion defining the backside surface of the second source/drain.

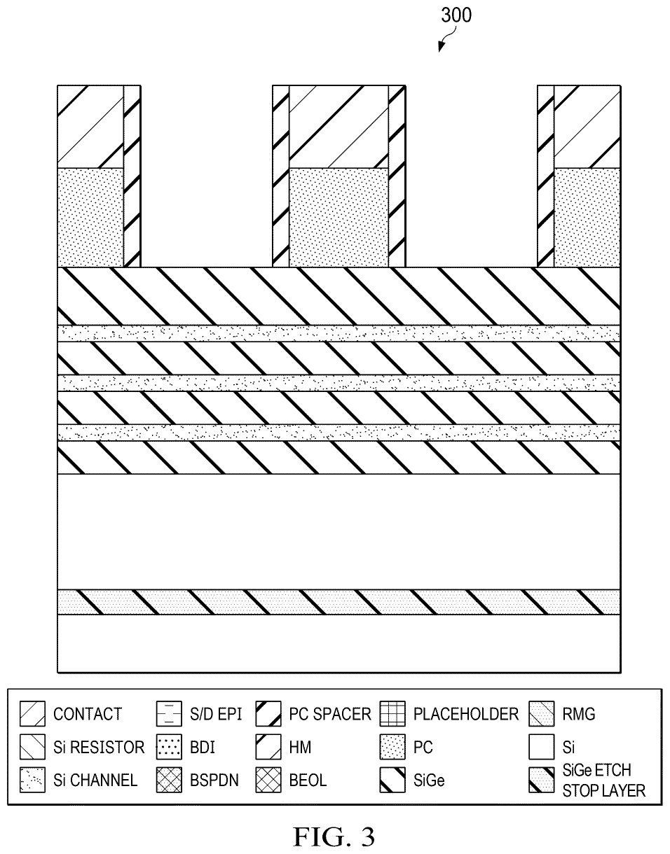

FIG. 3 shows a cross section of a partially completed component 300 after PC (gate module). The partially completed component 300 includes a plurality of nanosheet channels beneath a plurality of PC spacers.

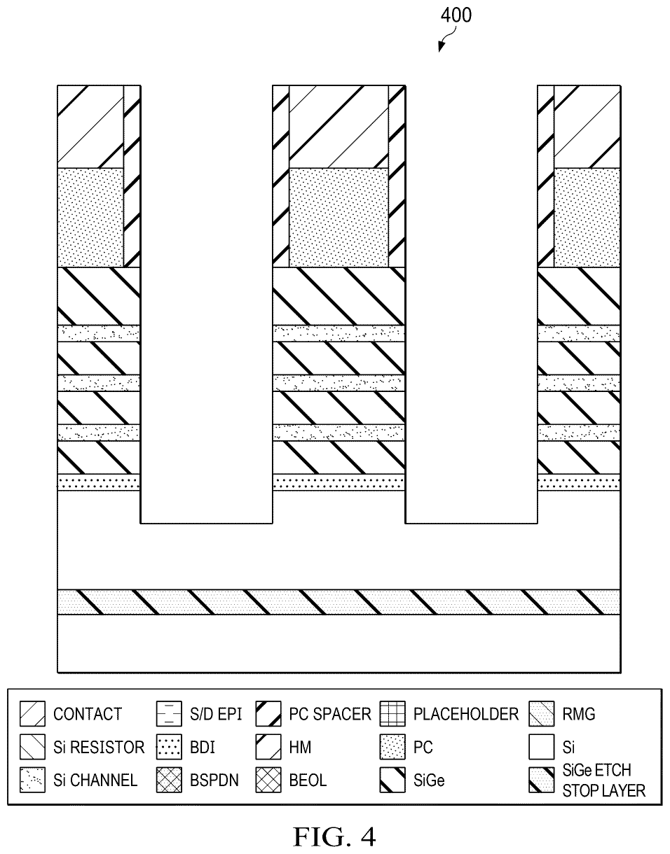

FIG. 4 shows a cross section of a partially completed component 400 after forming a first source/drain recess in the plurality of nanosheet channels beneath the first gate module recess and a second source/drain recess in the plurality of nanosheet channels beneath the second gate module recess.

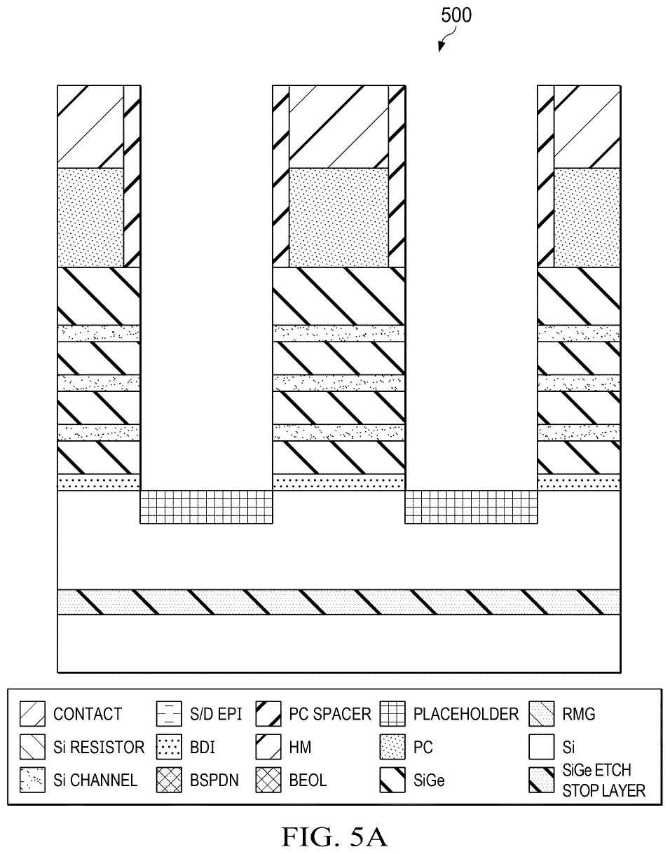

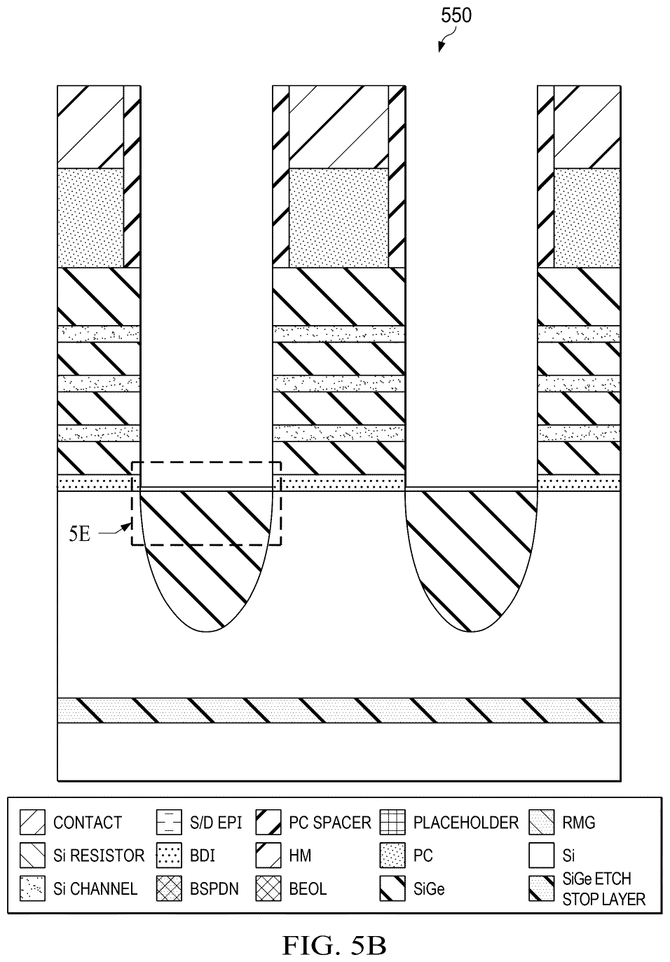

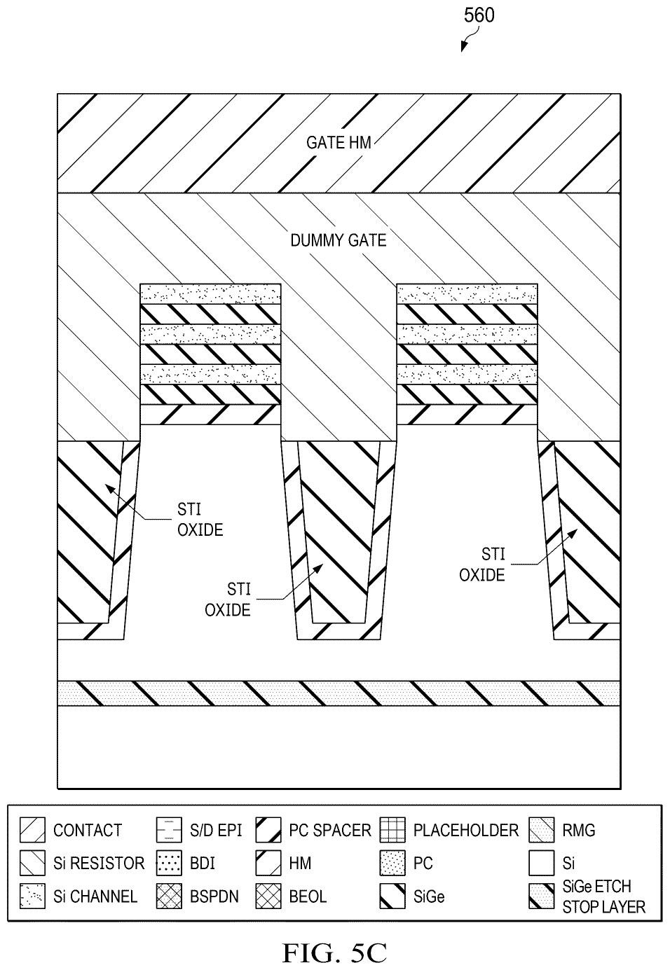

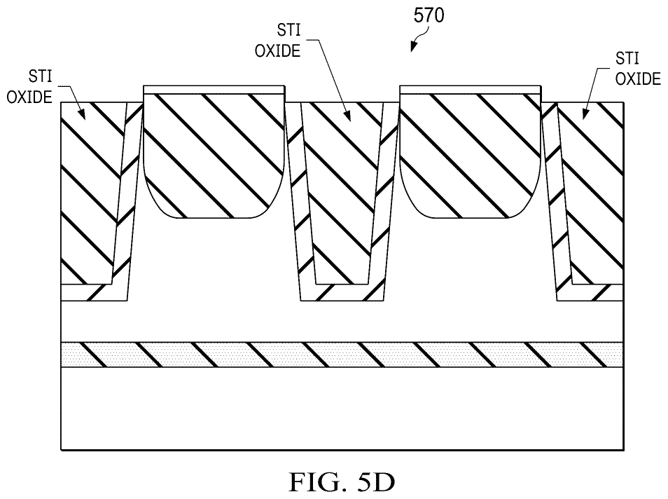

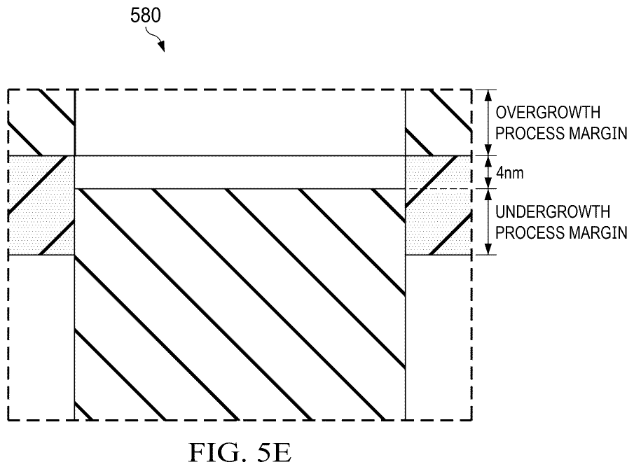

FIG. 5A shows a cross section of a partially completed component 500 after placeholder formation (for example, grow or deposit, then recess). FIG. 5B shows an X orientated cross section of a partially completed component 550 after placeholder formation. FIG. 5C shows a Y orientated cross section of a partially completed component 560. FIG. 5D shows a Y2 orientated cross section of a partially completed component 570. FIG. 5E shows a schematic 580 of target placeholder level from the cross section shown in FIG. 5B including for a placeholder with a total thickness of, for example, about 62 nm, overgrowth margin and undergrowth margins of approximately 6 nm, and placeholder position process variation margin of approximately plus/minus 10%, in a representative embodiment. Incidentally, a deeper cavity does not automatically mean under epitaxy growth. Similarly, a shallower cavity does not automatically mean over epitaxy growth.

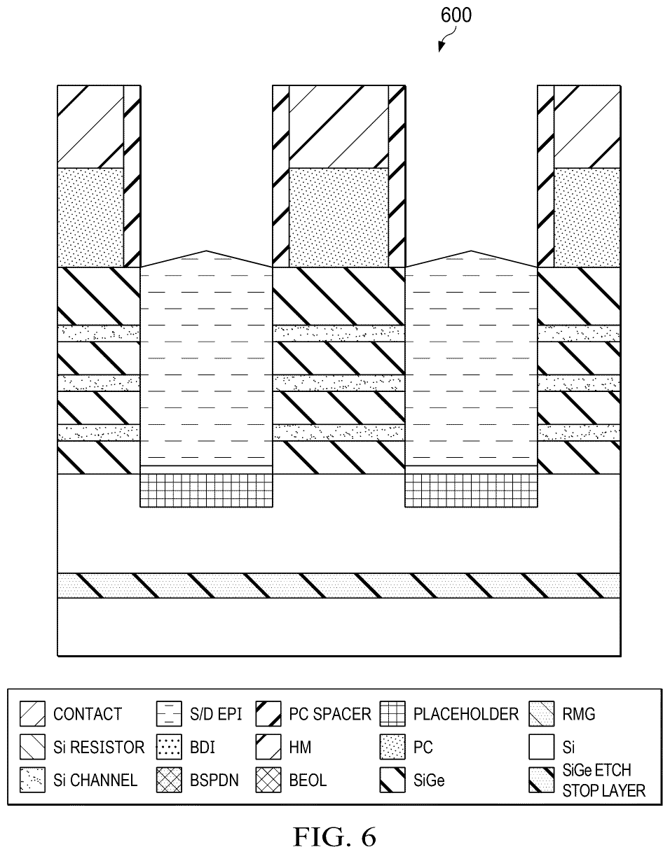

FIG. 6 shows a cross section of a partially completed component 600 after source/drain epitaxy formation.

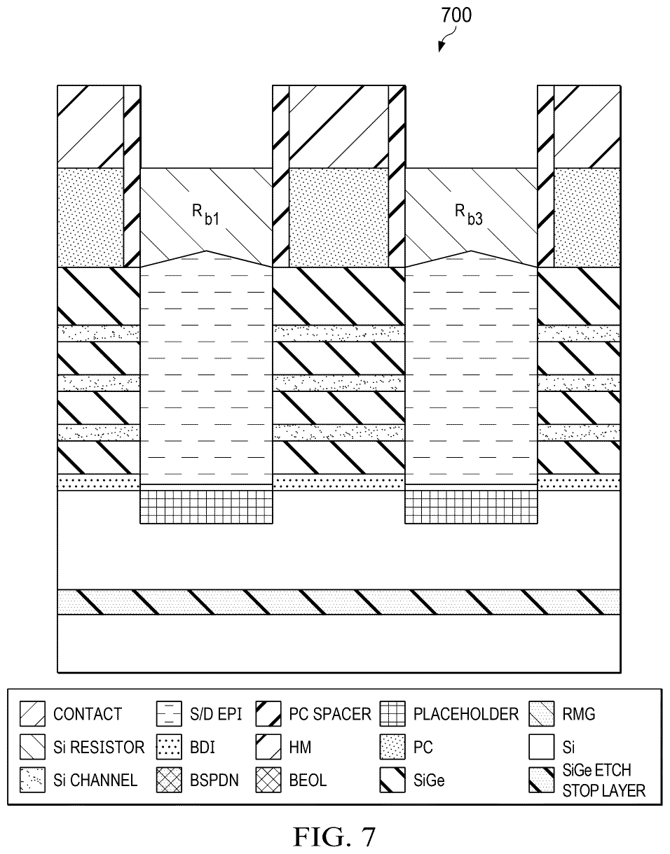

FIG. 7 shows a cross section of a partially completed component 700 after Selective formation of Si-based resistors R1 and R2. R1 and R2 may be formed selectively using in-situ doped low-temperature epitaxial growth of hydrogenated Si, e.g. using PECVD or HWCVD, which results in crystalline (single or poly) growth on the exposed parts of the source/drain epitaxy and in non-crystalline growth elsewhere. Subsequently, the non-crystalline portion of the hydrogenated Si is removed selectively using an appropriate dry or wet etch. In one example, etching is performed in-situ using a H₂ plasma. When R1 and R2 have the same resistance, they can be grown together using the same in-situ doping concentration. When R1 and R2 have different resistances, they can be grown separately (e.g. R1 is grown first and masked, followed by growing R2) using two different in-situ doping concentrations. Whether R1 and R2 have the same or different resistance values in any given memory cell in the array is determined by the photomask (hence, the mask programmability of the memory array). The details of the selective formation of the low-temperature hydrogenated epitaxial Si were disclosed in U.S. Ser. No. 13/032,866 (issued as U.S. Pat. No. 10,011,920 B2 in 2018).

Hydrogenated silicon (Si:H) may be grown by PECVD from a mixture of precursor gas SiH₄ (or other gases of the SiₓH_{y} family), carrier gas H₂ and dopant gas, such that [H₂]/[SiH₄]>5.

The growth is epitaxial (i.e. c-Si:H) on crystalline Si (c-Si) and non-crystalline Si (e.g. a-Si:H) elsewhere (e.g. on oxide or other insulators).

In some embodiments, hot-wire chemical vapor deposition (HWCVD) may be used instead of plasma-enhanced chemical vapor deposition (PECVD).

For n-type doping, the dopant gas may include PH₃. For p-type doping, the dopant gas may include B₂H₆ or TMB.

The c-Si:H has H content in the range of 5-40 atomic percent.

The H content in c-Si:H may or may not be uniform. In some embodiments, the H content has a gradient towards the c-Si:H/c-Si interface.

In some embodiments, the Si:H may further contain one or more of the following elements: D, F, CI, C, Ge, O, N.

In one embodiment, the a-Si:H is etched selectively with respect to c-Si:H with selectively in the range of 3:1-10:1. In another embodiment selectivity >10:1. In one embodiment, selective etch is performed in H plasma. In another embodiment a wet etch such as dilute KOH (˜1M or below) or dilute HF (<5% is DI water) is used. To build the complex structures that make up a transistor and the many wires that connect the millions of transistors of a circuit, lithography and etch pattern transfer steps are repeated multiple times. Each pattern being printed on the substrate is aligned to previously formed patterns, and gradually the conductive and insulative regions are built up to form the final device.

An embodiment of the nanosheet 1T-4R mask programed multi-level read-only memory component can include first, second, third and fourth resistors are comprised of hydrogenated crystalline Si (c-Si:H) with 5-40 atomic percent hydrogen. The first resistor, the second resistor, the third resistor, and the fourth resistor can be formed by deposition of in-situ doped hydrogenated crystalline silicon (c-Si:H) with 5-40 atomic percent hydrogen. The first resistor, the second resistor, the third resistor, and the fourth resistor can be formed by plasma-enhanced chemical vapor deposition (PECVD) or hot-wire chemical vapor deposition (HWCVD) of hydrogenated crystalline silicon (c-Si:H) at temperatures around 400 degrees Celsius.

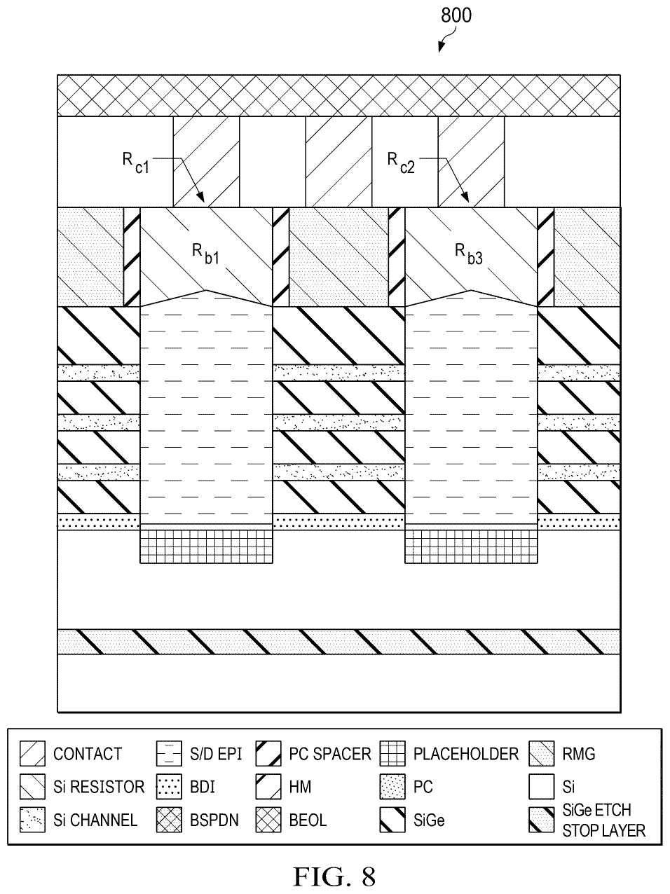

FIG. 8 shows a cross section of a partially completed component 800 after providing contacts and backend of line network. Note that contact resistance values (R_{c1}, R_{c2}, etc.) are doping dependent, with doping dependency becoming stronger (even exponential) at lower doping levels. For each doping level used for the bulk resistance (R_{b1}, R_{b2}, etc.) the corresponding contact resistance may be determined experimentally without undue experimentation (e.g. from calibration/control runs used for process development) and factored into the total desired resistance.

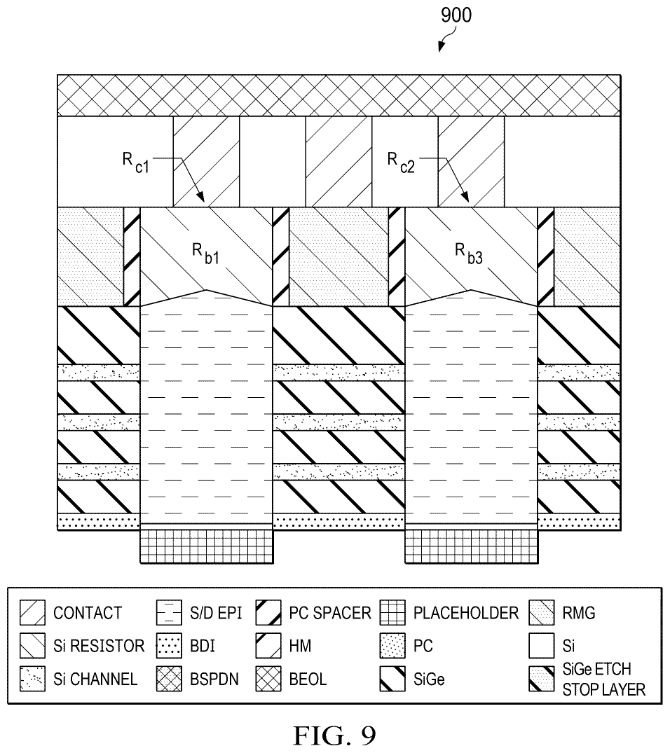

FIG. 9 shows a cross section of a partially completed component 900 after wafer flip and backside substrate removal. This exposes the placeholders.

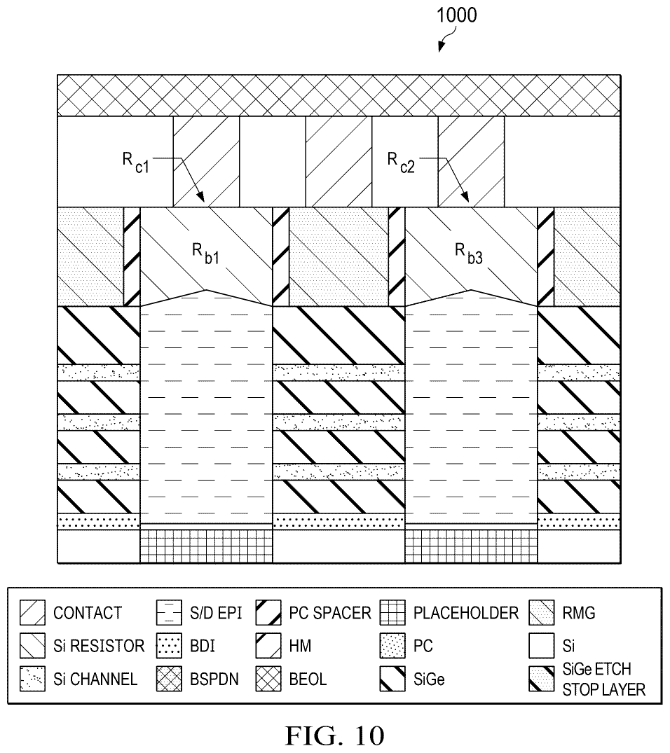

FIG. 10 shows a cross section of a partially completed component 1000 after backside ILD deposit and CMP.

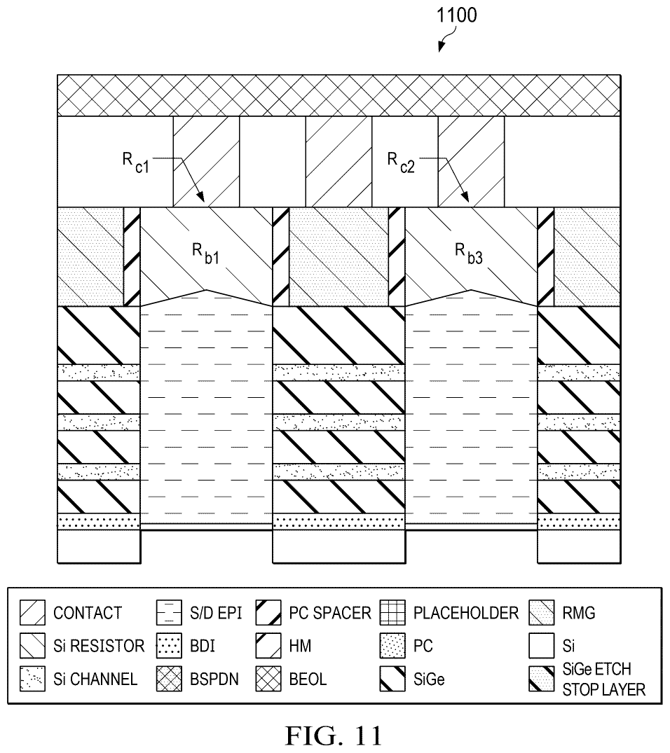

FIG. 11 shows a cross section of a partially completed component 1100 after placeholder removal.

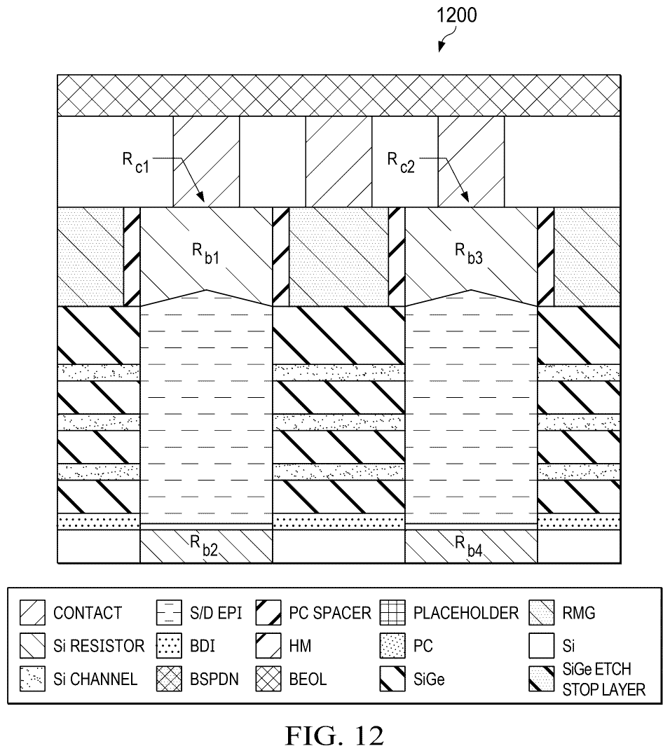

FIG. 12 shows a cross section of a partially completed component 1200 after backside Si growth and forming R3 and R4. R3 and R4 may be formed using the same technique described for R1 and R2. Similarly, R3 and R4 may have the same resistance (e.g. grown together with the same in-situ doping concentration) or different resistances (e.g. grown separately using two different in-situ doping concentrations). Again, whether R3 and R4 have the same or different resistance values in any given memory cell in the array is determined by the photomask.

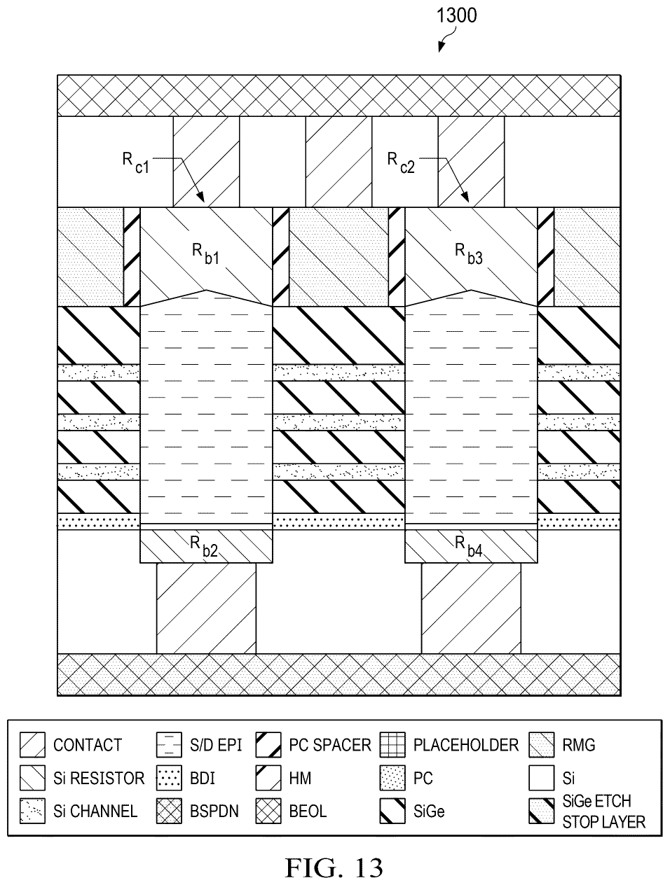

FIG. 13 shows a cross section of a partially completed component 1300 after forming the backside contacts and after BSPDN. An important aspect of embodiments is forming the self-aligned stack of resistor/epi/resistor, to minimize the device footprint. Each S/D epi has a resistor above connecting to the BEOL while that same S/D epi also connects with another resistor on the bottom connecting to the BSPDN.

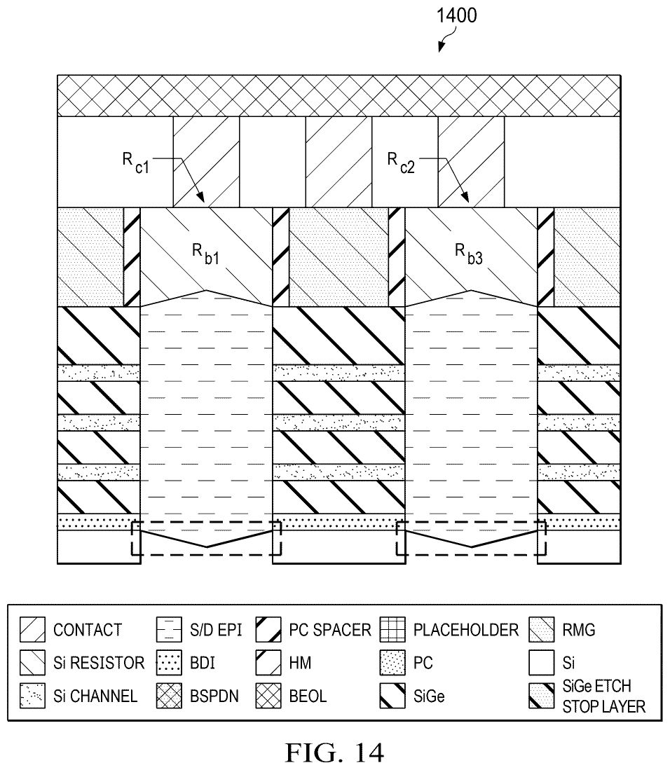

FIG. 14 shows a cross section of a partially completed component 1400 after backside S/D Epi extension. This illustrates another embodiment of the disclosure characterized by this backside S/D Epi extension.

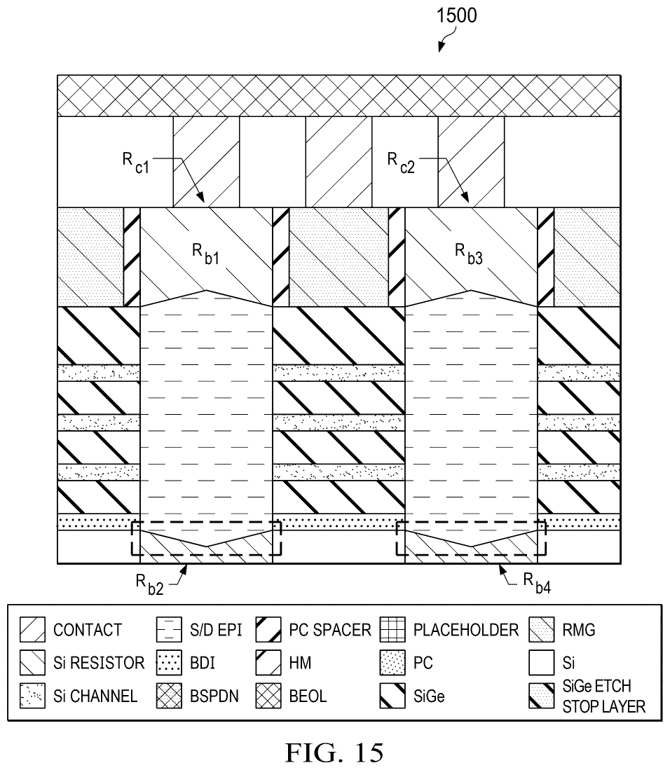

FIG. 15 shows a cross section of a partially completed component 1500 after backside Si growth and forming R3 and R4.

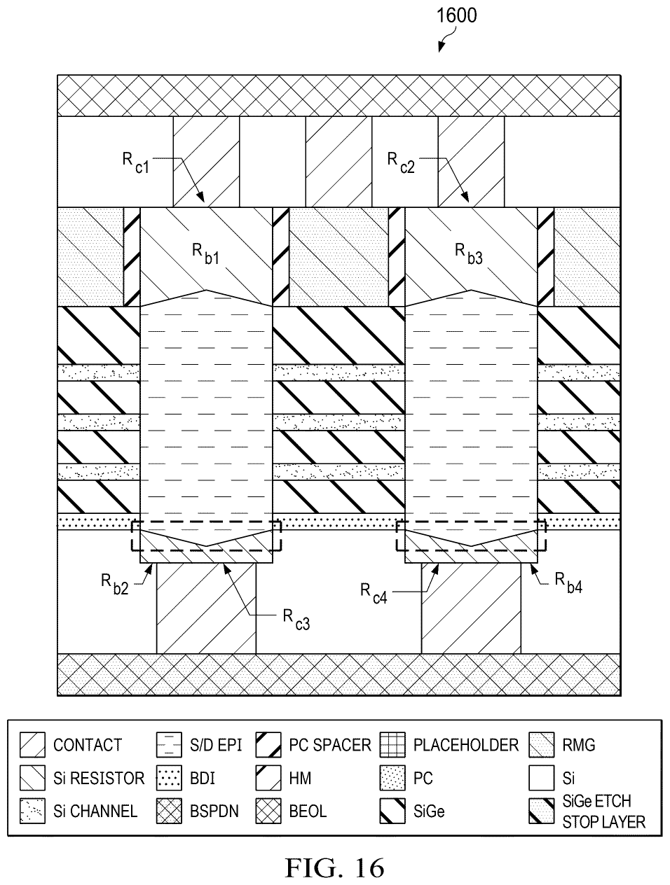

FIG. 16 shows a cross section of a partially completed component 1600 post backside contacts and BSPDN. Each S/D epi has a resistor on the top connecting to the BEOL while it also connects with another resistor on the bottom connecting to the BSPDN. The bottom interface of S/D epi and resistor is protruding toward the BSPDN (provide another process flexibility). This may provide a benefit in that a protruding interface between S/D epi and resistor provides a larger contact area and thus can reduce the Rc (contact resistance).

The flowchart and block diagrams in the Figures illustrate the architecture, functionality, and operation of possible implementations of systems and methods according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding of the various embodiments. But the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C,” may include item A, item A and item B, or item B. This example also may include item A, item B, and item C, or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A nanosheet 1T-4R mask programed multi-level read-only memory component, comprising:
a first source/drain;
a second source/drain;
a plurality of nanosheet channels between the first source/drain and the second source/drain;
a first resistor upon a frontside surface of the first source/drain;
a second resistor upon a frontside surface of the second source/drain;
a replacement metal gate above the plurality of nanosheet channels and around, but electrically isolated from, the first resistor and the second resistor;
a third resistor upon a backside surface of the first source/drain;
a fourth resistor upon a backside surface of the second source/drain;
a first contact electrically connecting the first resistor to a frontside backend of line network;
a second contact electrically connecting the third resistor to the frontside backend of line network;
a gate contact electrically connecting the replacement metal gate to the frontside backend of line network;
a third contact electrically connecting the third resistor to a backside power delivery network; and
a fourth contact electrically connecting the fourth resistor to the backside power delivery network.

2. The nanosheet 1T-4R mask programed multi-level read-only memory component of claim 1, wherein the gate comprises a metal gate.

3. The nanosheet 1T-4R mask programed multi-level read-only memory component of claim 1, wherein each of the plurality of nanosheet channels comprises a silicon nanosheet channel.

4. The nanosheet 1T-4R mask programed multi-level read-only memory component of claim 1, wherein the first source/drain comprises a first epitaxy deposited source/drain and the second source/drain comprises a second epitaxy deposited source/drain.

5. The nanosheet 1T-4R mask programed multi-level read-only memory component of claim 1, wherein the first resistor comprises a first silicon based resistor, the second resistor comprises a second silicon based resistor, the third resistor comprises a third silicon based resistor, and the fourth resistor comprises a fourth silicon based resistor.

6. The nanosheet 1T-4R mask programed multi-level read-only memory component of claim 1, wherein the first, second, third and fourth resistors are comprised of hydrogenated crystalline Si (c-Si:H) with 5-40 atomic percent hydrogen.

7. The nanosheet 1T-4R mask programed multi-level read-only memory component of claim 1, wherein the first resistor, the second resistor, the third resistor, and the fourth resistor define a high-resistance set and a low-resistance set based on 2 different doping concentrations.

8. The nanosheet 1T-4R mask programed multi-level read-only memory component of claim 1, further comprising a bottom dielectric isolation located beneath the plurality of nanosheet channels.

9. The nanosheet 1T-4R mask programed multi-level read-only memory component of claim 1, wherein the first source/drain comprises a first protruding frontside end providing a first contact area and the second source/drain comprises a second protruding frontside end providing a second contact area.

10. The nanosheet 1T-4R mask programed multi-level read-only memory component of claim 9, wherein the first source/drain comprises a first protruding backside end providing a first contact area and the second source/drain comprises a second protruding backside end providing a second contact area.

11. The nanosheet 1T-4R mask programed multi-level read-only memory component of claim 1, wherein the first source/drain comprises a first protruding backside end providing a first contact area and the second source/drain comprises a second protruding backside end providing a second contact area.

12. A method of forming a nanosheet 1T-4R mask programed multi-level read-only memory component, the method comprising:
providing a plurality of nanosheet channels above a bottom dielectric isolation and beneath a plurality of PC spacers;
forming a first gate module recess and a second gate module recess in the plurality of nanosheet channels;
forming a first source/drain recess in the plurality of nanosheet channels beneath the first gate module recess and a second source/drain recess in the plurality of nanosheet channels beneath the second gate module recess;
depositing a first placeholder into a silicon layer at a bottom of the first source/drain recess and a second placeholder into the silicon layer at a bottom of the second source/drain recess;
depositing a first source/drain in the first source/drain recess above the first placeholder and a second source/drain in the second source/drain recess above the second placeholder;
depositing a first resistor electrically coupled to a frontside surface of the first source/drain and adjacent at least one of the PC spacers and a second resistor electrically coupled to a frontside surface of the second source/drain adjacent at least one of the PC spacers;
depositing a replacement metal gate between the first resistor and the second resistor, above the plurality of nanosheet channels and adjacent at least two of the PC spacers;
depositing a first contact electrically coupled to the first resistor, a second contact electrically coupled to the second resistor, and a gate contact electrically coupled to the replacement metal gate;
depositing a backend of line network electrically coupled to the first contact, the second contact, and the gate contact;
removing the silicon layer from around the first placeholder and the second placeholder to expose the first placeholder, the second placeholder, and the bottom dielectric isolation;
depositing a layer around the first placeholder and the second placeholder;
removing the first placeholder and the second placeholder;
depositing a third resistor electrically coupled to a backside surface of the first source/drain and a fourth resistor electrically coupled to a backside surface of the second source drain;
depositing a third contact electrically coupled to the third resistor and a fourth contact electrically coupled to the fourth resistor; and
depositing a backside power delivery network electrically connecting the third contact and electrically connecting the fourth contact.

13. The method of claim 11, wherein depositing the first source/drain in the first source/drain recess above the first placeholder and the second source/drain in the second source/drain recess above the second placeholder includes
forming a first frontside protrusion defining the frontside surface of the first source/drain, and
forming a second frontside protrusion define the frontside surface of the second source/drain.

14. The method of claim 13, wherein forming the nanosheet 1T-4R mask programed multi-level read-only memory component includes
forming a first backside protrusion defining the backside surface of the first source/drain, and
forming a second backside protrusion defining the backside surface of the second source/drain.

15. The method of claim 12, wherein forming the nanosheet 1T-4R mask programed multi-level read-only memory component includes
forming a first backside protrusion defining the backside surface of the first source/drain, and
forming a second backside protrusion defining the backside surface of the second source/drain.

16. The method of claim 12, wherein the first resistor, the second resistor, the third resistor, and the fourth resistor define a high-resistance set and a low-resistance set based on two different doping concentrations.

17. The method of claim 12, wherein the first resistor, the second resistor, the third resistor, and the fourth resistor are formed by deposition of in-situ doped hydrogenated crystalline silicon (c-Si:H) with 5-40 atomic percent hydrogen.

18. The method of claim 12, wherein the first resistor, the second resistor, the third resistor, and the fourth resistor are formed by plasma-enhanced chemical vapor deposition (PECVD) or hot-wire chemical vapor deposition (HWCVD) of hydrogenated crystalline silicon (c-Si:H) at temperatures around 400 degrees Celsius.

19. A nanosheet 1T-4R mask programed multi-level read-only memory component, comprising:
a first source/drain;
a second source/drain;
a plurality of nanosheet channels between the first source/drain and the second source/drain;
a first resistor upon a frontside surface of the first source/drain;
a second resistor upon a frontside surface of the second source/drain;
a replacement metal gate above the plurality of nanosheet channels and around, but electrically isolated from, the first resistor and the second resistor;
a third resistor upon a backside surface of the first source/drain;
a fourth resistor upon a backside surface of the second source/drain;
a first contact electrically connecting the first resistor to a frontside backend of line network;
a second contact electrically connecting the third resistor to the frontside backend of line network;
a gate contact electrically connecting the replacement metal gate to the frontside backend of line network;
a third contact electrically connecting the third resistor to a backside power delivery network; and
a fourth contact electrically connecting the fourth resistor to the backside power delivery network,
wherein the first, second, third and fourth resistors are comprised of hydrogenated crystalline Si (c-Si:H) with 5-40 atomic percent hydrogen, and
wherein the first resistor, the second resistor, the third resistor, and the fourth resistor define a high-resistance set and a low-resistance set based on 2 different doping concentrations.

20. The nanosheet 1T-4R mask programed multi-level read-only memory component of claim 19, wherein the first source/drain comprises a first epitaxy deposited source/drain and the second source/drain comprises a second epitaxy deposited source/drain.
